(19) United States
(12) Patent Application Publication
(10) Pub. No.: US 2021/0143307 A1
(43) Pub. Date: May 13, 2021

(54) MODULES AND ELEMENTS FOR A THERMOELECTRIC GENERATOR

(71) Applicant: Sumitomo Chemical Company Limited, Tokyo (JP)

(72) Inventors: Thomas Fletcher, Godmanchester (GB); Simon King, Godmanchester (GB)

(73) Assignee: Sumitomo Chemical Company Limited, Tokyo (JP)

(21) Appl. No.: 16/623,331

(22) PCT Filed: Jun. 14, 2018
(86) PCT No.: PCT/GB2018/051628

§ 371 Date: Dec. 16, 2019

(30) Foreign Application Priority Data
Jun. 19, 2017 (GB) 1709726.2

(51) Int. Cl. H01L 35/32; H01L 35/08; H01L 35/34

(52) U.S. Cl. CPC H01L 35/32; H01L 35/34; H01L 35/08

(57) ABSTRACT

Thermoelectric elements and modules for thermoelectric generators with low electrical resistance and/or improved thermovoltage, excellent mechanical stability and flexibility. The thermoelectric elements and modules include stack-type thermoelectric legs formed by lamination of at least two layers comprising semiconductive materials. An adhesive layer may be used to laminate the two layers of semiconductive materials and the stack-type thermoelectric legs may be fabricated by solution deposition methods.

### BACKGROUND

Embodiments of the present disclsoure relate to modules and elements for a thermoelectric generator comprising stack-type thermoelectric legs formed by lamination of at least two layers, where each of the at least two layers comprise semiconductive materials. Further embodiments of the present disclsoure relate to a method of manufacturing the modules and elements for a thermoelectric generator.

Recently, printable thermoelectric generators (TEGs) have attracted considerable research interest since TEGs enable realization of flexible, large-area modules for conversion of thermal energy into electricity, which may be manufactured and processed at low costs by using solution processing techniques.

The fabrication of TEGs and/or thermoelectric modules typically involves the formation of p- and n-type semiconducting legs connected electrically in series and thermally perpendicular to the heat gradient, which may be surrounded by bank material, wherein the resulting semiconducting legs/layers are disposed between two substrates between which a temperature gradient is applied. While many efforts have been made to develop new materials, which are both amenable to solution processing and exhibit a favourable thermoelectric performance—e.g. optimized electrical conductivity, Seebeck coefficient (which represents a measure of the magnitude of an induced thermoelectric voltage in response to a temperature difference across the material), power factor and a low heat conductivity—the efficiency characteristics of known flexible and printed thermoelectric generators still leave room for improvement.

To enable favourable device efficiency, the applied temperature gradient must be transferred efficiently to the active thermoelectric materials. Generally, this may be achieved by reducing the thermal resistance of the substrates and by increasing the thermal resistance of the active layer, e.g. the semiconducting legs. The latter effect may be obtained by increasing the thickness of the active layer. However, in known device structures, the maximum thickness of solution-deposited active layers is limited to approximately 60 μm in view of difficulties in the processing of the bank and semiconductor raw materials. While the use of materials having relatively high viscosities may in principle enable higher active layer thicknesses, the deposition, curing and/or developing of such materials is difficult.

Another problem often observed in conventional TEG designs is the lateral disconnection in conductive (or electrode) layers formed on the active layer (for example, due to surface topology, differing mechanical properties of the bank material and the active thermoelectric materials and/or upon bending and flexing), which may severely impact the internal resistance of the device and thereby reduce its power output. One proposed solution involves the selection of materials, which exhibit similar thermal expansion coefficients. However, such selcection criteria severely limits the choice of materials and does not provide satisfactory stress relief when subjecting the resulting thermoelectric module to bending and flexing.

U.S. Pat. No. 8,779,276 B2 shows an alternative method for assembling a TEG via the combination of complementary patterned substrates. However, as the resulting TEG structures do not include metal electrodes and the p-type and n-type materials are in direct lateral contact, undesirably high contact and bulk lateral resistances may be produced.

In view of the above, there exists a need to provide TEGs, thermoelectric elements and modules, which exhibit low electrical resistance and/or improved thermovoltage, excellent mechanical stability and flexibility, and which may be easily processed by solution deposition methods.

### SUMMARY

Embodiments of the present disclosure solve these objects with the subject matter of the claims as defined herein. The advantages of the present disclosure will be further explained in detail in the section below and further advantages will become apparent to the skilled artisan upon consideration of the application.

The present inventors found that thermoelectric elements, wherein thermoelectric legs have been formed by lamination of a plurality of semiconductive material-containing layers—which may be processed easily by conventional solution deposition methods—exhibit excellent electrical conductivity, remarkably enhanced thermovoltage, and mechanical strength, thus enabling production of robust thermoelectric devices with excellent thermoelectric conversion efficiency.

Generally speaking, embodiments of the present disclsoure relate to a thermoelectric element for a TEG/thermoelectric module, comprising a first substrate and a second substrate with an intermediate layer sandwiched between the first and the second substrate. The intermediate layer comprises a first sub-layer comprising a first electrode provided over the first substrate and a first semiconductive layer provided over the first electrode, a second sub-layer comprising a second electrode provided over the second substrate and a second semiconductive layer provided over the second electrode. In this arrangement, the hermoelectric legs comprise a stack-type structure and being spaced apart from each other are formed by electrical contact between the first and second semiconductive layers. In embodiments of the present disclosure, the electrical contact is established by lamination of the first and second sub-layers.

In a second aspect, some mbodiments of the present disclsoure relate to a TEG/thermoelectric module comprising a plurality of said thermoelectric elements.

In a third aspect, some embodiments of the present disclsoure relate to a method of manufacturing the thermoelectric elements. The method comprising: providing a first sub-layer on a first substrate by depositing a first electrode onto the first substrate and a first semiconductive layer over the first electrode; providing a second sub-layer on a second substrate by depositing a second electrode onto the second substrate and a second semiconductive layer over the second electrode; optionally providing a first conductive interlayer on the first semiconductive layer and/or a second conductive interlayer on the second semiconductive layer; and laminating the first and second sub-layers to each other so as to establish electrical contact between the first and second semiconductive layers.

Preferred embodiments of the formulation according to the present invention and other aspects of the present invention are described in the following description and the claims.

### BRIEF DESCRIPTION OF THE DRAWINGS

FIG. 1a schematically illustrates the general architecture of an exemplary thermoelectric element comprising n-type and p-type legs. The depicted battery is not an essential element of the invention.

FIG. 1b illustrates a thermoelectric device comprising a plurality of thermoelectric elements. The depicted battery is not an essential element of the invention.

FIG. 2a is a diagram illustrating the preparation of an exemplary thermoelectric element according to the present disclosure. The depicted battery is not an essential element of the invention

FIG. 2b is a diagram illustrating an exemplary thermoelectric element according to the present disclosure. The depicted battery is not an essential element of the invention.

FIG. 3a illustrates potential lateral disconnections in conventional single-layer designs.

FIG. 3b illustrates the effects of lateral disconnections in embodiments of the present disclosure.

FIG. 4 shows a comparison of open circuit voltages of different TEG architectures.

### DETAILED DESCRIPTION

For a more complete understanding of the present invention, reference is now made to the following description of the illustrative embodiments thereof:

### Thermoelectric Elements & Modules

Commercially available thermoelectric modules are usually found in two different configurations, one being a vertical configuration, which consists of a plurality of thermocouples connected in series and sandwiched between a thermally conductive hot plate and cold plate. Such thermocouples consist of a p-type leg and an n-type leg connected in series, each of which may consist of a series configuration of multiple materials in order to maximize the efficiency. Another type of thermoelectric module is the lateral configuration, which follows the same principle of the vertical type with the main difference that the heat source is located in the right or left side of the module.

An example of a conventional thermoelectric element having a vertical geometry is shown in FIG. 1a. The depicted thermoelectric element comprises a thermoelectric junction between an n-type material and p-type material having different Seebeck coefficients, which generally take the shape of n-type (3) and p-type (4) legs arranged between electrically-insulating substrates (1a and 1b), optionally with conductor layers/electrical shunt layers (2a, 2b and 2c) or interface material layers (not depicted) provided therebetween. Such junctions particularly enable to generate electric power when they are submitted to a temperature gradient (as that between the upper high temperature side and the lower low temperature side in FIG. 1a, for example), or to generate a temperature gradient when they are crossed by an electric current.

A representation of an exemplary thermoelectric module is depicted in FIG. 1b, wherein elements in accordance with FIG. 1 a are connected electrically in series and thermally in parallel. The battery as depicted in these Figures (and also depicted in Figures further described below) is not an essential element of the present invention. It is in particular not required for the mode of operation where electric power is generated by a temperature gradient. The battery however may be present in the mode of operation where electric current is used to generate a temperature gradient. In this case the battery may serve as a source for the required electric power. As the skilled person will be aware, in such an embodiment, the orientation of the battery determines the orientation of the temperature gradient to be generated.

Deviating from the thermoelectric element design of FIG. 1a, in accordance with some embodiments of the present disclosure, a thermoelectric element is provided preferably having a vertical geometry comprising: a first substrate and a second substrate; an intermediate layer sandwiched between the first and the second substrate, the intermediate layer comprising: a first sub-layer comprising a first electrode provided over the first substrate and a first semiconductive layer provided over the first electrode, a second sub-layer comprising a second electrode provided over the second substrate and a second semiconductive layer provided over the second electrode; wherein thermoelectric legs having a stack-type structure and being spaced apart from each other are formed by electrical contact between the first and second semiconductive layers, the electrical contact being established by lamination of the first and second sub-layers.

The maximum power transferred from a power source occurs when the load resistance matches that of the internal resistance. For a TEG the open circuit voltage U is determined by the combined Seebeck coefficient of the p-type and n-type materials multiplied by the temperature gradient across the materials. For efficient operation in a typical TEG design, the temperature gradient applied across the device must be transferred with minimal losses across the substrates to the active materials, which may be achieved by reducing the thermal resistance of the substrates and increasing the thermal resistance of the active layer.

By configuring the thermoelectric element according to the present disclosure, it becomes possible to increase the nominal thickness and hence the thermal resistance of the active layer, thereby enabling a facilitated production of thermoelectric elements with improved thermovoltage without facing the difficulties involved with the processing of high viscosity materials. In this regard, it may be thus preferred that the sum of thicknesses of the first and the second semiconductive layers is 60 μm or more, preferably 70 μm or more, further preferably 80 μm or more, especially preferably 100 μm or more.

The materials used for the first and second substrate layers may be suitably selected by the skilled artisan from substrate materials known in the art. Examples thereof include, but are not limited to glass, ceramics and plastics (e.g., polyethylene naphthalate (PEN), polyethylene terephthalate (PET), polyimide (PI), polycarbonate (PC), polyethersulphone (PES), polymethyl metacrylate (PMMA), polydimethylsiloxane (PDMS), polyurethane (PU), acrylate based polymers, etc.).

The first sub-layer comprises a first electrode and a first semiconductive layer provided thereon, wherein the first electrode is positioned over or faces towards the first substrate. In analogy, the second sub-layer comprises a second electrode and a second semiconductive layer, wherein the layer forming the second electrode being arranged in proximity of the second substrate. It is understood that the first and the second sub-layers may be composed of the same materials (which may be preferable from the viewpoint of simpler processing) or may be composed of different materials (e.g. different semiconductive materials or electrode materials).

The materials used for the first and second electrode layers may be suitably selected by the skilled artisan and typically include conductive metals (e.g. Ag, Au and Al), conductive metal oxides, or mixtures thereof (e.g. Al/Al₂O₃).

By lamination of the first and second sub-layers, the first and second semiconductive layers form thermoelectric legs having a stack-type structure.

It is understood that although a thermoelectric unit or couple typically comprises n-and p-type legs in view of the improved thermovoltage and efficiency, both are not strictly necessary, since functioning devices may also be manufactured by using only one type (e.g. either n or p, when coupled with an electrical shunt or conductor layer).

In order to form pairs of p-type and n-type leg pairs, the first semiconductive layer may comprise n- and p-type semiconductive members that are spaced apart from each other and are arranged in a first pattern, and the second semiconductive layer may comprise n- and p-type semiconductive member pairs that are spaced apart from each other and are arranged in a second pattern, wherein it is ensured that electrical contact between the n-type members of the first and second semiconductive layers and electrical contact between the p-type members of the first and second semiconductive layers is established upon lamination, for example, by forming the first pattern as a plane mirror image of the second pattern.

The material for the p-type legs used in this configuration is not particularly limited and may be selected from known organic and inorganic p-type semiconducting thermoelectric materials, including, but not limited to p-doped conductive polymers (e.g., polypyrroles, polyaniline (PANI), polythiophene and their derivatives (e.g., poly(3-hexylthiophene-2,5-diyl (P3HT) and poly(3,4-ethylenedioxythiophene:polystyrene sulfonate (PEDOT:PSS)), inorganic p-doped materials (e.g., mechanical alloyed metals including elemental bismuth, antimony, and tellurium, doped with tellurium, bismuth or selenium), and combinations thereof (e.g., carbon nanoparticles in polymeric matrices).

The material for the n-type legs is likewise not particularly limited and may be selected from known organic and inorganic n-type semiconducting thermoelectric materials, including, but not limited to, n-type organic small molecules (e. g. n-type dopants based on 4-(2,3-Dihydro-1,3-dimethyl-1H-benzimidazol-2-yl)-N,N-dimethylbenzenamine (N-DMBI) precursor, such as 2-(2-Methoxyphenyl)-1,3-dimethyl-1H-benzoimidazol-3-ium iodide), n-doped fullerene and/or fullerene derivatives, perylenediimides, n-doped conductive polymers (e.g. naphthalenediimide-based polymers and derivatives thereof), organometallic coordination polymers, and n-doped inorganic materials.

Preferred materials for n-type legs include printable n-doped inorganic materials (e.g., alloys based on bismuth in combinations with antimony, tellurium or selenium, such as Bi₂Te₃; or alloys based on zinc and antimony) and n-doped fullerene and/or fullerene derivatives (such as a functionalized fullerene, and preferably a PCBM-type fullerene derivative). Such derivatives include [6,6]-phenyl-C61-butyric acid methyl ester (C₆₀PCBM), [6,6]-phenyl-C71-butyric acid methyl ester (C₇₀PCBM), [6,6]-phenyl-C85-butyric acid methyl ester (C₈₄PCBM), and mixtures and adducts thereof, for example. Further preferably, the PCBM-type fullerene derivative is [6,6]-phenyl-C61-butyric acid methyl ester (C₆₀PCBM). Preferably, the n-type dopant is selected from the group of non-polymeric electron donors and/or reducing agents.

As preferred examples thereof in terms of stability under ambient conditions, imidazole derivatives and tetraalkylammonium salts (e.g. tetrabutylammonium fluoride) may be mentioned. N-type dopants based on imidazole derivative precursors are further preferred n-type dopants, and benzoimidazole derivatives are especially preferable in view of en excellent solution processability. Specific examples of benzoimidazole derivative precursors include, but are not limited to DMBI derivatives, such as e.g. (4-(1,3-dimethyl-2,3-dihydro-1H-benzoimidazole-2-yl)-phenyl)-dimethyl-amine (N-DMBI), 2-(2,4-dichlorophenyl)-1,3-dimethyl-2,3-dihydro-1H-benzoimidazole (Cl-DMBI), 2-(1,3-dimethyl-2,3-dihydro-1H-benzoimidazol-2-yl)-phenol (OH-DMBI), and 1 ,2,3-trimethyl-2-phenyl-2,3-dihydro-1H-benzoimidazole (TMBI). In an especially preferred embodiment, the n-type dopant is based on the precursor N-DMBI.

It is understood that the n- and p-type semiconducting legs may comprise additional materials (including additional polymers, conductive particles, antioxidants, light or resistance enhancing agents, plasticizers etc.).

Preferably, the first and/or second sub-layers may further comprise electrically insulating material (also referred to as bank material in the present disclosure) between the semiconductive layers forming the thermoelectric legs, which advantageously provides a support for the thermoelectric materials on the first and/or second substrates, enables a more regular thermoelectric leg spacing for an enhanced contact area and potentially allows to achieve an increased fill factor (F), the latter being defined as the ratio of the total cross section area of active thermoelectric material (of the thermoelectric legs) to the total surface area of the substrate. The electrically insulating materials are not particularly limited and may be selected by the skilled artisan from materials known in the art. Preferred electrically insulating materials also exhibit thermally insulating properties. Specific examples include, but are not limited to polymers, resins and/or photoresist materials (including epoxy-based resins or polyimide and its derivatives, for example).

In another preferred embodiment, the thermoelectric element further comprises an adhesive layer which establishes the electrical contact between the first sub-layer and the second sub-layer.

In this respect, it is noted that the adhesive layer may be provided on the edges of the thermoelectric element or module (e.g., so as to surround the first and second sub-layers), or surround a pattern formed by the first semiconductive layer and/or the second semiconductive layer (such as the first and second patterns referred to above), so that there is no substantial contact between the adhesive and the thermoelectric legs. In such a case, the type of adhesive may be selected from any known adhesive provided that the electrical contact between the first and second semiconductive layers is ensured.

In an alternatively preferred embodiment, the adhesive layer is provided directly between the first and second semiconductive layers.

In an especially preferred embodiment, the adhesive layer is provided between the semiconductive materials constituting the thermoelectric legs so that is comprised in the stack-type structure of the semiconducting legs. In such a case, the adhesive layer may comprise an anisotropically conductive adhesive, which is commonly known and commercially available as z-axis (conductive) adhesive. Anisotropically conductive adhesives are typically a mixture of a nonconductive adhesive binder and conductive particles capable of forming electrically conductive paths between facing conductive surface areas, where the conductive particles are sufficiently separated from each other so that current will not flow through the composite mass, thereby establishing electrical conductivity in a single axis only. In some embodiments of the present disclsoure, use of z-axis adhesives may be made to establish vertical electrical connectivity between the sub-layers and thereby avoid the risk of breakage and disconnection occurring in conventional devices requiring lateral connectivity between semiconducting legs, as will be further explained below with reference to FIGS. 3a and 3b.

As an alternative to the use of z-axis adhesives, the adhesive layer may also comprise an electrically conductive adhesive which is provided in a pattern onto the semiconductor layers so as to only enable electrical contact between the appropriate legs of each sub-layer. In such a configuration, the nature of the adhesive is not particularly limited as long as it enables sufficient electrical conductivity. As examples thereof, adhesives comprising polymers (e.g., epoxy, acrylic, phenoxy, polyimide, silicone, fluoropolymer) and electro-conductive particles (e.g., metal particles and alloys including Au, Ag, Pt, Pd, Ni, Cu, Al, Sn, Zn, Ti, Sn, BI, W, Pb; carbon black, carbon fibers, and graphite) may be mentioned. Preferred embodiments may include polymer-based adhesives (e.g. epoxy) comprising silver particles.

In another preferred embodiment, the thermoelectric element of the present application may comprise a conductive interlayer between the first and second semiconductive layers, which may be composed of a single layer or of multiple sub-layers between the semiconductive materials in the first and second sub-layers forming the thermoelectric legs, and which may serve to enhance the electrical contact between the semiconductive materials upon lamination. In the presence of an adhesive layer between the first and second semiconductive layers, it may be preferable that a first conductive interlayer is provided between the first semiconductive layer and the adhesive layer and/or a second conductive interlayer is provided between the second semiconductive layer and the adhesive layer.

It is understood that the thermoelectric element according to the present disclosure may also comprise additional layers. For example, a third sub-layer comprising a third semiconductive material may be provided between the first and second sub-layer in order to further to increase the nominal thickness of the thermoelectric material layer (or height of the stack-type thermoelectric leg, respectively) and hence the thermal resistance of the active layer.

It will also be appreciated that the preferred features of the first embodiment specified above may be combined in any combination, except for combinations where at least some of the features are mutually exclusive.

A second embodiment of the present disclsoure relates to a thermoelectric module comprising a plurality of the thermoelectric elements described in the first embodiment.

While it is understood that the present disclsoure is not limited thereto, an example of a thermoelectric module according to the present disclsoure is shown in FIGS. 2a and 2b. The thermoelectric module depicted in FIG. 2b comprises a intermediate layer (10) sandwiched between a first (11a) and a second substrate layer (11b) which is formed by lamination of a first sub-layer (10a) and a second sub-layer (10b) through an anisotropically conductive adhesive layer (16), as is illustrated in FIG. 2a. The first sub-layer (10a) comprises a first electrode (12a) provided in contact with the first substrate (11a) and a first semiconductive layer (13a) provided in contact with the first electrode (12a), whereas the second sub-layer (10b) comprises a second electrode (12b) provided in contact with the second substrate (11b) and a second semiconductive layer (13b) provided in contact with the second electrode (12b), wherein electrically insulating bank material (15) fills the lateral spaces between the semiconductive (13a/13b) and electrode layers (12a/12b). First/second conductive interlayers (14a/14b) between the first/second semiconductive layers (13a/13b)) and the adhesive layer (16) enable enhanced electrical contact between the semiconductive material constituting the stack-type thermoelectric legs. Each of the first and second semiconductive layers (13a/13b) comprise n- and p-type semiconductive members that are spaced apart from each other and are arranged in a first and a second pattern, respectively, the first pattern being a mirror image of the second pattern relative to the lamination plane (i.e. adhesive layer (16)).

In general, it is emphasized that the mechanical properties of thermoelectric materials may be critical for both device manufacturing and operation. Because each thermoelectric leg is held rigidly in place to the electrical interconnect, significant stresses may be build up in the material. In addition, differences between the thermal expansion coefficients between the materials constituting the semiconducting legs, interface layers, conductive/electrode layers may lead to additional stress, particularly in view of the high operation temperatures and thermal cycling in potential TEG applications. As a result, lateral disconnection is often observed in conventional TEG designs, which may severely inhibit the lateral current flow and reduce the power output. Potential disconnections are illustrated in FIG. 3a and include underfilling (A), lifting off (B) and crack formation (C) and are mainly observed at areas, wherein the electrical interconnect (or electrode layer) (24) is deposited onto the semiconducting legs (23a).

In contrast, in the thermoelectric elements of the present disclosure, lateral connectivity is provided by the electrode layers that are remote from the area of potential maximum stress.

In addition, as is illustrated in FIG. 3b, if typical disconnect actions as observed in conventional TEG devices occur in thermoelectric element or modules of the present disclsoure, the functioning and performance of the device is not affected as long as the vertical connectivity is maintained, which is both observed in thermoelectric elements without adhesive layers between the semiconductive portions (not depicted) and to a larger extent in elements with a z-axis adhesive provided inbetween (as in FIG. 3b).

Moreover, in conventionally laminated printed devices there is the potential for a thermal contact resistance to form between printed surfaces and a substrate layer which is subsequently provided on the printed surfaces due to poor contact area. A thermal contact resistance here can impact device performance as the applied temperature gradient will not be transferred effectively to the active material. When material is deposited as a solution an intimate contact is made to the substrate which is ideal for heat transfer. Therefore, in the case of the TEG design of the present disclosure, the thermal contact resistance from substrate to material is removed, further enhancing the thermal efficiency. Additionally, it may be expected that a thermal contact resistance will be generated at the lamination interface due to non-uniform topology and changes in material (i.e. transfer across adhesive), particularly in areas where bank meets bank. However, in this case a high thermal resistance is desirable as it acts to increase the temperature gradient across the active materials.

In summary, the the first and second embodiments of the present dislcsoure described above provide thermoelectric elements and modules, which exhibit low electrical resistance and/or improved thermovoltage, excellent mechanical stability and flexibility, and which may be easily processed by solution deposition methods

### Method for Manufacturing of Thermoelectric Elements & Modules

A third embodiment of the present application provides a method of manufacturing a thermoelectric element. The manufacturing method comprises: providing a first sub-layer on a first substrate by depositing a first electrode onto the first substrate and a first semiconductive layer over the first electrode; providing a second sub-layer on a second substrate by depositing a second electrode onto the second substrate and a second semiconductive layer over the second electrode; optionally providing a first conductive interlayer on the first semiconductive layer and/or a second conductive interlayer on the second semiconductive layer; and laminating the first and second sub-layers to each other so as to establish electrical contact between the first and second semiconductive layers. Each of the components of the thermoelectric element may be constituted from the materials described in connection with the first and second embodiments, and the resulting thermoelectric element may have any of the constitutions as set out in the description of the first embodiment.

In a preferred embodiment, the first semiconductive layer comprises a plurality of n-and p-type semiconductive member pairs that are spaced apart from each other and are arranged in a first pattern; wherein the second semiconductive layer comprises a plurality of n- and p-type semiconductive member pairs that are spaced apart from each other and are arranged in a second pattern; and wherein the first pattern is a mirror image of the second pattern relative to the lamination plane (e.g. plane of the adhesive layer, if present). With thermoelectric legs formed on each substrate they are then laminated together with adhesive such that the printed legs contact each other, with contacts made from p-type to p-type and n-type to n-type, and the first and second electrodes link the thermoelectric junctions in series (in analogy to FIG. 2a).

In another preferred embodiment, lamination is effected through an adhesive layer positioned between the first sub-layer and the second sub-layer. Further preferably, the adhesive layer surrounds a pattern formed by the first semiconductive layer and/or the second semiconductive layer; or wherein the adhesive layer is provided between the first and second semiconductive layers and comprises a z-axis anisotropic conductive adhesive. Depending on the type of z-axis adhesive, its use may require application of pressure during the curing process in order to capture a monolayer of conductive particles between the surfaces to be laminated. Other techniques involve heat or UV-curing of z-axis adhesive matrices in the presence of a magnetic field in order to align the conductive filler particles.

It may be preferable that the providing a first sub-layer on a first substrate by depositing a first electrode onto the first substrate and a first semiconductive layer over the first electrode comprises providing a first electrically insulating layer comprising one or more holes (or wells) vertically above the first electrode layer, and the first semiconductive layer is formed by depositing semiconductive material(s) into the hole(s) of the first electrically insulating layer. And providing a second sub-layer on a second substrate by depositing a second electrode onto the second substrate and a second semiconductive layer over the second electrode comprises a second electrically insulating layer comprising one or more holes positioned vertically above the second electrode layer, and the second semiconductive layer is formed by depositing semiconductive material(s) into the hole(s) of the second electrically insulating layer.

The methods of depositing the first and second electrodes and the optional first and second conductive interlayers are not particularly limited and may include electron beam method, sputtering, coating, evaporation (e.g. vacuum evaporation) and solution deposition (e.g. by using metal-filled polymer solutions).

While not being limited thereto, it is preferable that the first and second semiconductive layers, further preferably the entire first and second sub-layers are deposited by solution deposition techniques, which advantageously ensures intimate contact to the substrate and hence optimized heat transfer. It is understood that the first and the second sub-layers may be composed of the same materials (which may be preferable from the viewpoint of simpler processing)

The solution deposition techniques include but are not limited to coating or printing or microdispensing methods like for example spin coating, spray coating, web printing, brush coating, dip coating, slot-die printing, ink jet printing, letter-press printing, stencil printing, screen printing, doctor blade coating, roller printing, offset lithography printing, flexographic printing, or pad printing. Preferably, the solution deposition method is an inkjet printing, stencil printing, screen printing, dispense printing or drop casting method, more preferably a stencil printing, screen printing, dispense printing or inkjet printing method, which provide for a scalable route to manufacture. Inkjet printing generally involves the ejection of a fixed quantity of a liquid phase, i.e. ink, in form of droplets from a chamber through a nozzle. The ejected drops are provided onto a substrate to form a pattern. While solidification of the liquid drops may be brought about through chemical changes or crystallization, solvent evaporation is commonly used, in some cases by exposing the deposited wet film to high temperature and/or reduced pressure, preferably immediately upon printing. The solvents used for solution deposition of each of the components may be identical or different and may be suitably selected by the skilled artisan in view of their compatibility, boiling point and the processing conditions. In addition, a blend of multiple solvents may be used for each of the species to be dissolved.

Depending on the desired architecture of the thermoelectric element, the method may comprise steps of depositing additional layers. It is understood that the methods for provision of those layers is not particularly limited and includes any methods known to the skilled artisan.

The method according to the present disclosure has the advantage that it enables rapid and easy fabrication of flexible and mechanically robust thermoelectric elements and modules, which may be processed at low costs by using solution processing techniques, and at the same time exhibit enhanced device performance (e.g. high thermovoltage and/or low electrical resistance). Moreover, the method avoids the need for difficult production processes using materials having relatively high viscosities.

It will be appreciated that the preferred features of the first to third embodiments specified above may be combined in any combination, except for combinations where at least some of the features are mutually exclusive.

### EXAMPLES

### Example 1

A device according to the present disclsoure was fabricated by using polyethylene naphthalate (PEN) as first and second substrate layers, each having a thickness of 125 μm. First and second electrode layers were formed on the substrates by the sputtering of 200 nm thick layers of aluminium capped with 30 nm thick layers of gold. Subsequently, electrically insulating bank material (SU-8, commercially available from Microchem Corp.) was deposited onto each of the substrates at a thickness of 60 μm by spin coating andμphotolithography, with a plurality of wells vertically above the first and second electrode layers. Thereafter, p-type material (PEDOT:PSS (Heraeus Clevios PH1000) with 5% DMSO added) and n-type material (PCBM:PS:N-DMBI) was deposited as into the wells of the bank material by dispense printing. Conductive interlayers were deposited onto the semiconductive members of each substrate by evaporation through a shadow mask of gold (30 nm) and aluminium (1 μm). Adhesive film was applied around the TEG active area on the second substrate and then the two assemblies were laminated together using cold rollers such that the evaporated metal electrodes on each part contacted to form the TEG circuit.

### Comparative Example 1

As a comparative example, a device having a classical architecture has been manufactured, by preparing and laminating a device according to Example 1, with the exception that on one of the substrates, only an electrode layer has been deposited and the bank and thermoelectric material has been omitted.

To generate a voltage, each of the devices were clamped between two temperature controlled aluminium blocks with thermal grease to reduce thermal contact resistance. A temperature gradient of —15<dT<+15 K was applied to the device and the resulting voltage was measured with a Keithley 2001 multimeter after the temperature gradient had stabilized at each setpoint.

As is shown in FIG. 4, the thermoelectric module according to the present disclosure exhibits a remarkably enhanced Seebeck voltage (approximately double) over the equivalent device using a conventional architecture.

Hence, it has been shown that the thermoelectric elements and modules according to the present disclosure exhibit excellent performance and may be easily processed by solution deposition methods.

Once given the above disclosure, many other features, modifications, and improvements will become apparent to the skilled artisan.

### REFERENCE NUMERALS

1a/11a: first substrate layer
1b/11b: second substrate layer
2a/12a/22a: first electrode/conductor layer
2b/12b/22b: second electrode/conductor layer
3: n-type leg
4: p-type leg
10: intermediate layer
10a: first sub-layer
10b: second sub-layer
13a/23a: first semiconductor layer
13b/23b: second semiconductor layer
24: electrode/conductor layer (lateral interconnect)
14a/24a: first conductive interlayer
14b/24b: second conductive interlayer
15: electrically insulating material
15a/25a: first electrically insulating material layer
15b/25b: second electrically insulating material layer
16/26: z-axis anisotropically conductive adhesive layer

1. A thermoelectric element, comprising:
a first substrate and a second substrate;
an intermediate layer sandwiched between the first and the second substrate, the intermediate layer comprising:
a first sub-layer comprising a first electrode provided over the first substrate and a first semiconductive layer provided over the first electrode,
a second sub-layer comprising a second electrode provided over the second substrate and a second semiconductive layer provided over the second electrode;
wherein thermoelectric legs having a stack-type structure and being spaced apart from each other are formed by electrical contact between the first and second semiconductive layers, and wherein the electrical contact is established by an adhesive layer laminated between the first and second sub-layers.

2. The thermoelectric element according to claim 1, wherein the adhesive layer comprises an electrically conductive adhesive and is provided between the first and second semiconductive layers in a pattern that enables electrical contact between the first and second semiconductive layers and prevents lateral electrical contact between the thermoelectric legs.

3. The thermoelectric element according to claim 1, wherein the adhesive layer comprises a z-axis anisotropically conductive adhesive.

4. The thermoelectric element according to claim 1, wherein the adhesive layer surrounds a pattern formed by the first semiconductive layer and/or the second semiconductive layer.

5. The thermoelectric element according to claim 1, wherein a conductive interlayer is provided between the first and second semiconductive layers.

6. The thermoelectric element according to claim 5, wherein a first conductive interlayer is provided between the first semiconductive layer and the adhesive layer and/or a second conductive interlayer is provided between the second semiconductive layer and the adhesive layer.

7. The thermoelectric element according to claim 1, further comprising electrically insulating material disposed between the thermoelectric legs.

8. The thermoelectric element according to claim 1, wherein the sum of thicknesses of the first and the second semiconductive layers is 60 μm or more.

9. A thermoelectric module comprising a plurality of thermoelectric elements according to claim 1.

10. A method of manufacturing a thermoelectric element, comprising the steps of:
providing a first sub-layer on a first substrate by depositing a first electrode onto the first substrate and a first semiconductive layer over the first electrode;
providing a second sub-layer on a second substrate by depositing a second electrode onto the second substrate and a second semiconductive layer over the second electrode; optionally providing a first conductive interlayer on the first semiconductive layer and/or a second conductive interlayer on the second semiconductive layer; and
laminating the first and second sub-layers to each other so as to establish electrical contact between the first and second semiconductive layers.

11. The method of manufacturing a thermoelectric element according to claim 10, wherein the first and second semiconductive layers are preferably deposited by solution deposition techniques.

12. The method of manufacturing a thermoelectric element according to claim 10, wherein the first semiconductive layer comprises a plurality of n- and p-type semiconductive member pairs that are spaced apart from each other and are arranged in a first pattern; wherein the second semiconductive layer comprises a plurality of n- and p-type semiconductive member pairs that are spaced apart from each other and are arranged in a second pattern; and wherein the first pattern is a mirror image of the second pattern relative to the lamination plane.

13. The method of manufacturing a thermoelectric element according to claim 10, wherein laminating the first and second sub-layers to each other so as to establish electrical contact between the first and second semiconductive sub-layers comprises lamination using adhesive layer positioned between the first sub-layer and the second sub-layer to adhere the first semiconductive sub-layer to the second semiconductive layers sub-layer and to establish electrical contact between the first and second semiconductive sub-layers.

14. The method of manufacturing a thermoelectric element according to claim 13, wherein the adhesive layer surrounds a pattern formed by the first semiconductive layer and/or the second semiconductive layer; wherein the adhesive layer is provided between the first and second semiconductive layers and comprises a z-axis anisotropically conductive adhesive; or wherein the adhesive layer comprises an electrically conductive adhesive and is provided between the first and second semiconductive layers in a pattern which enables electrical contact between the first and second semiconductive layers but no electrical contact between the thermoelectric legs.

15. The method of manufacturing a thermoelectric element according to claim 10, wherein, providing the first sub-layer on the first substrate by depositing the first electrode onto the first substrate and the first semiconductive layer over the first electrode comprises providing a first electrically insulating layer comprising one or more holes vertically above the first electrode layer over at least the first electrode layer, and the first semiconductive layer is formed by depositing semiconductive material(s) into the hole(s) of the first electrically insulating layer.

16. The method of manufacturing a thermoelectric element according to claim 10, wherein,
providing the second sub-layer on the second substrate by depositing the second electrode onto the second substrate and the second semiconductive layer over the second electrode comprises providing a second electrically insulating layer comprising one or more holes vertically above the second electrode layer over at least the second electrode layer, and the second semiconductive layer is formed by depositing semiconductive material(s) into the hole(s) of the second electrically insulating layer.
